(19) United States
(12) Patent Application Publication
(10) Pub. No.: US 2006/0108676 A1
(43) Pub. Date: May 25, 2006

(54) Multi-chip package using an interposer

(76) Inventors: Nelson V. Punzalan JR., San Pablo City (PH); Marcelino Ian W. Estinozo, Quezon City (PH)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(21) Appl. No.: 10/994,984

(22) Filed: Nov. 22, 2004

(51) Int. Cl. H01L 21/48; H01L 23/02

(52) U.S. Cl. 257/686; 438/109; 257/784; 438/617

(57) ABSTRACT

A method and apparatus for multi-chip packages that are closely coupled using an interposer is disclosed. A top single chip or multi-chip encapsulated package with bottom side contacts is formed and tested. A bottom single chip or multi-chip package substrate having bottom contacts is formed. Then a hollow center interposer is connected to the periphery of the package substrate leaving the chips at the center exposed, and the hollow region is filled with an encapsulant to the level of the top of the interposer, to form the finished package having contact on the bottom and on the top. After the bottom package undergoes electrical function testing, the top package is soldered to the interposer forming a completed multi-chip package.

### TECHNICAL FIELD

Various embodiments described herein relate generally to attaching multiple integrated circuit packages together using interposers, and more specifically to coupling integrated circuit (“IC”) packages together.

### BACKGROUND INFORMATION

Many electronic devices have space and operational speed requirements that may require more than one IC to occupy a single package area on a printed circuit board (“PCB”), or other electronic device connection means. It is known to use multiple unpackaged IC chips stacked on top of one another and wired bonded to a single package substrate, which is then encapsulated and appears similar to a single IC package, but having multiple IC chips enclosed. This may be known as a thin stack chip package, and it provides a method of placing many IC chips on essentially the same area of a PCB as a single IC chip package. However, the density of wire bonds and the multiple levels of the wire bonds may cause short circuits caused by what is known as wire sweep due to long wire lengths during encapsulation, or shorts due to vibrational or handling induced wire displacement. Another issue with forming multi-chip IC packages is that the individual ICs often can not be completely electrically function tested before packaging. Thus, the percent yield of good packages may be greatly decreased because of the poor individual IC chip failure yield rate due to using untested ICs. Yet a third issue with placing large numbers of ICs into a single package is the need to make the individual IC chips thinner than usual, prior to stacking them on top of one another, to keep the overall height of the package at practical levels. The cost and yield loss associated with back-lap polishing of IC chips reduces the practicality of including more than two IC chips in each IC package. Yet a fourth issue with multi-chip IC packages is failure analysis of the entire group of many individual IC chips, and separating out which individual chip represents the failure location. Yet a fifth issue with multi-chip IC packages is that the individual IC chips need to be sequentially smaller as the stack increases in height in order to be able to wire bond the periphery of each chip.

One method to avoid the poor yield, wire bond short circuits and other problems associated with multi-chip IC packages, is to form either individual packages or multi-chip packages with only one or two ICs in each package, and then electrically function test the packages. The separately tested packages may then be attached to opposite sides, and at different locations, on what is known as a flex film circuit. The flex film circuit is then folded so that one package is folded or flopped on top of the other. This may be known as folded stack chip package. This packaging method may result in better yield since each package has fewer ICs, the packages have been pre-tested, and it still only uses a little more PCB area than a single IC chip package. However, the electrical properties of the folded flex film circuit are not as good as a single multi-chip package. The signal propagation times are much longer, and the signal voltage drops are much larger than in a single multi-chip package. This is due to the relatively long signal path length between the output contacts on the top package, along the sideways length of the flex film circuit out past the end of the top and bottom packages far enough to allow the flex film circuit to bend 180 degrees without damage, and back sideways to the bottom output contacts on the bottom package. In addition, the folded and bent region of the flex film circuit is a high stress region and may result in reliability and operational lifetime issues.

### BRIEF DESCRIPTION OF THE DRAWINGS

FIGS. 1A, 1B and 1C are cross sectional side views of prior art;

FIGS. 2A, 2B, 2C and 2D are cross sectional side views of exemplary embodiments;

FIGS. 3A, 3B and 3C are block diagrams of an exemplary embodiment; and

FIG. 4 is a block diagram of a system according to various embodiments of the invention.

### DETAILED DESCRIPTION

In the following detailed description of embodiments of the inventive subject matter, reference is made to the accompanying figures which form a part thereof, and in which is shown by way of illustration, specific preferred embodiments of ways in which the inventive subject matter may be practiced. These embodiments are described in sufficient detail to enable those skilled in the art to practice the inventive subject matter, and it is to be understood that other embodiments may be utilized, and that mechanical, compositional, structural, electrical, and procedural changes may be made to the embodiments disclosed herein without departing from the scope, spirit and principles of the present inventive subject matter. The following detailed description is, therefore, not to be taken in a limiting sense, and the scope of the inventive subject matter is defined only by the appended claims. In the drawings, like numerals describe substantially similar components.

The term “IC package” as used herein, refers to the material surrounding an IC chip or die, that substantially protects the IC chip and electrically connects the electrical signal input and output (“I/O”) pads on the IC chip to signal conductors that travel either to external I/O connectors, or to other I/O pads on the same IC chip, or to I/O pads on other IC chips in the same package. The other IC chips in the same package may be situated on top of, underneath, or laterally displaced in a horizontal direction from each other. The term “package substrate”, as used herein, refers to a portion of what may become an IC package with further processing and assembly, and is that portion of the IC package to which the IC chip or chips are electrically attached.

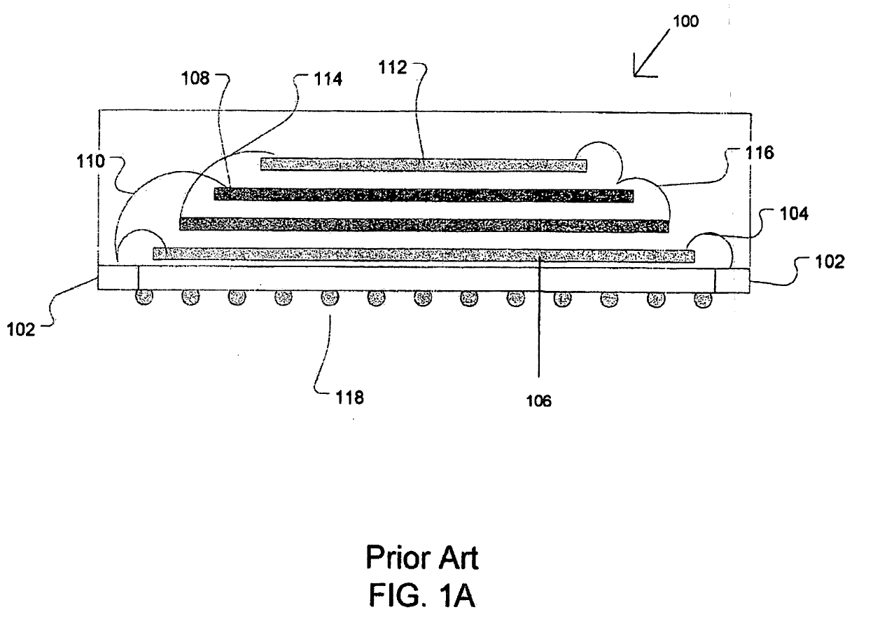

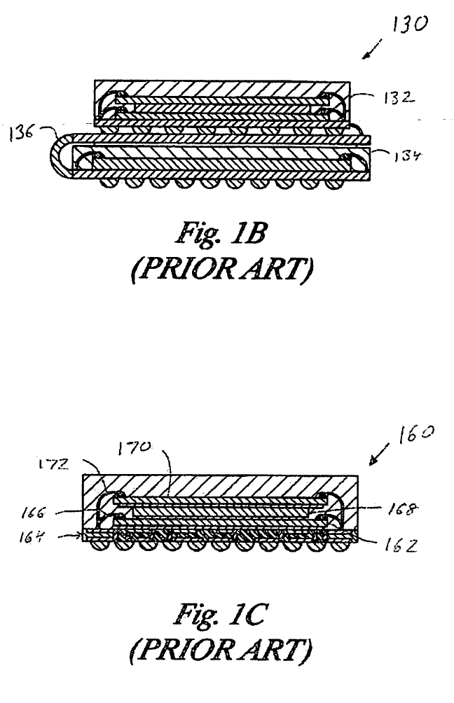

FIG. 1A, is a side view of a prior art IC multi-chip package. In FIG. 1A a multi-chip package 100 has a package substrate 102 that extends in several sections along essentially the entire bottom portion of the package 100. The package substrate 102 may have a single layer of conductive lines in the two outer sections that are not directly underneath the IC chips, at least some of which may be used for wire bonds to the IC chips, or the package substrate 102 may have multiple layers of conductive lines to serve as electrical interconnection in all three sections of package substrate 102. The package substrate 102 may be electrically connected via wire bonds 104 to an IC chip 106. IC chip 106 is typically physically connected to the package substrate 102 by a die attach material (not shown for clarity) such as an epoxy.

In a multi-chip package there may typically be two, three, four or more IC chips mounted one above another, and each individual IC chip may typically be attached to the IC chip below by means of the die attach material, for example epoxy. Each individual one of the IC chips, for example IC chip 108, may typically have wire bond connections 110 to the package substrate 102, in the same fashion as the first IC chip 104. However, the difference in wire bonding height between IC chips 104 and 108 may cause problems with the automated bonding systems, and may result in wire bond failures. The IC chips in a multi-chip package may have wire bonds that do not connect directly to the package substrate 102. For example the IC chip 112 has wire bonds 114 that connect to the IC chip two below, and wire bonds 116 that connect to the IC chip 108.

After the wirebonding of the various IC chips, the package substrate 102 may typically have the top surface and the IC chips encapsulated by a plastic material to protect the IC chips and wire bonds from scratches and external contamination. This forms the multi-chip package. After encapsulation, the multi-chip package may have solder bumps 118 placed on the bottom surface of the package for solder connection typically to a PCB, or other electronic device interconnect device. Note that each one of the four shown IC chips must be smaller than the IC chip located below in order to allow space for wire bonding. This may limit the design choices of the system using the IC chips, and may limit which specific IC chips may be placed in a multi-chip package having three or more vertically stacked IC chips.

FIG. 1B, is a side view of a prior art IC multi-chip package. In FIG. 1B a folded stack chip package 130 comprising an upper multi-chip package 132 and a lower package 134, both of which are attached to what is known as a flex film 136. As noted previously this type of package results in a final printed circuit board IC footprint that is slightly larger than a single IC package, but adds a longer signal path and reliability concerns due to the 180 degree turn made by the signal wire traces in the flex film.

FIG. 1C, is a side view of a prior art IC multi-chip package. In FIG. 1C what is known as an ultrathin stack chip package 160 is shown having an lower IC chip 162 attached and wire bonded to the conductor portion 164 of the package 160 by wire bonds 166. A middle IC chip 168 is attached to the lower IC chip 162 by a die attach material located between the middle IC 168 and the lower IC 162. A third IC 170 is attached to the middle IC 168 by a die attach material, and may be wire bonded to the conductor portion of the package 160 by wire bonds 172. Each of the IC chips 162, 168 and 170 may be chemically/mechanically thinned to prevent the overall thickness of package 160 from becoming too thick. In this illustrative prior art example the middle IC 168 is shown as having a horizontal dimension that is less than the upper IC 170, resulting in an inability to wire bond the IC 168 to the conductor portion 164 of the package 160. This may be required by design considerations where an existing IC chip may need to be electrically connected as closely as possible to another IC chip for reasons of signal delay. As a result it may be necessary to have the middle IC 168 electrically attached to the lower IC 162 by means of what is known as flip chip bonding. The ultrathin stack chip package may have more IC chips than those shown in this illustration, and because it may not be possible to completely electrically test each individual one of the ICs 162, 168 and 170 prior to attaching them to the package 160, it is likely that the overall yield of electrically good packages 160 may be unacceptably low. There is a further potential yield loss in the extra process of thinning the ICs.

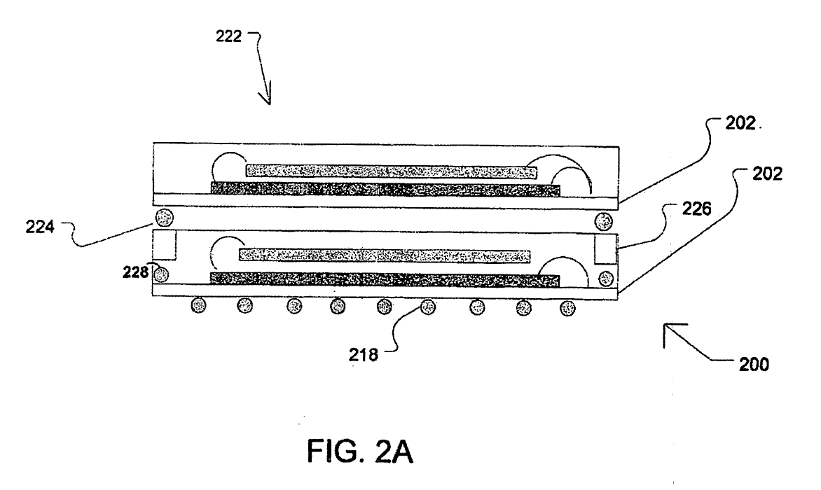

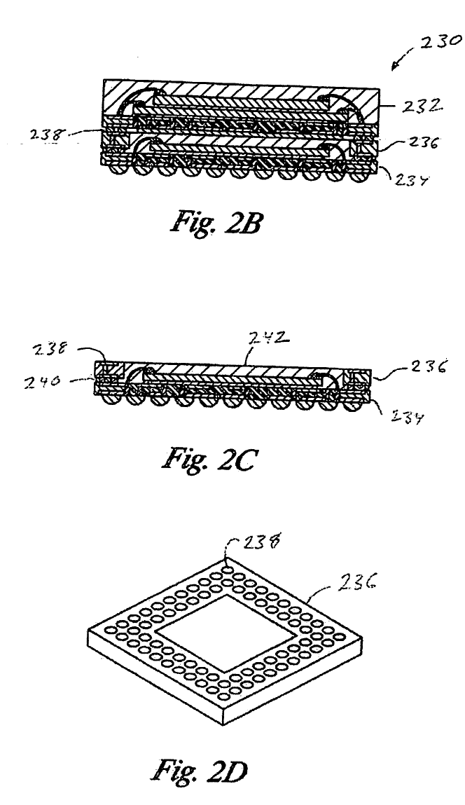

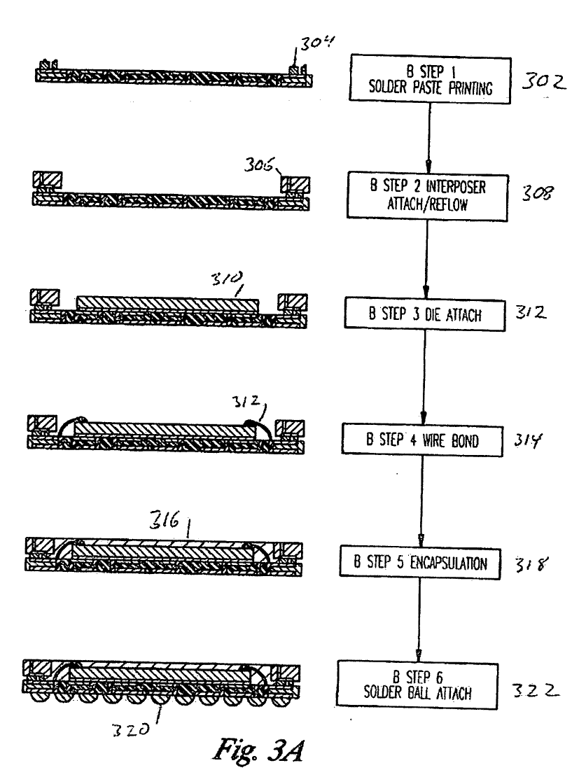

FIG. 2A is a cross sectional side view of an exemplary embodiment. FIG. 2A shows two separate packages, 200 and 222. Each package contains similar features to one another, and to the multi-chip package shown in FIG. 1A, and similar components have similar numbers in both figures. The packages 200 and 222 are shown as both being multi-chip packages, but the embodiment is not so limited, and either the package 200 or the package 222 may be a single chip package, or may have three or more IC chips. FIG. 2A also shows that in each of the packages 200 and 222 the upper IC chip, if any, may be smaller than the lower IC for wire bonding purposes, but the embodiment is not so limited, and approximately equal sized IC chips may be used if one of the IC chips is attached to the package by what may be known as flip chip mounting.

The multi-chip packages 200 and 222, may be electrically connected to one another by connectors 224, which may be solder balls or solder paste that has been reflowed. The connectors may be located between a package substrate 202 on a bottom surface of multi-chip package 222, and an interposer 226 located on a top surface of multi-chip package 200. The interposer 226 may be connected to a package substrate 202, on a bottom surface of multi-chip package 200 by connectors 228, which may be solder balls or solder paste that has been reflowed. As discussed previously, the IC chips may be physically connected to the package substrates 202, and to each other, by means of die attach material, not shown for clarity, for example epoxy or other appropriate die attach materials.

FIG. 2A shows that the electrical signal paths from multi-chip package 222 to multi-chip package 200 are very short, and thus may be referred to as closely coupled, as compared to the flex film folded stack chip package. Thus, the electrical performance properties of the shown closely coupled stacked packages may be improved over the folded stack chip package previously discussed which had long, folded electrical signal conductors. The reliability of the closely coupled stacked package may also be improved over the flex film folded stack chip package because there are no bent and stressed signal conductor lines. The cost of the shown multi-chip package may be lower than the flex film folded stack chip package because of the simpler and more automated assembly technique, and the absence of the flex film component. It is to be noted that while the illustrative embodiment shown in the figure uses wire bonding for the chip to package electrical connections the embodiment is not so limited and other methods such as flip chip attach may be used.

FIG. 2A shows that the wire bonding of the IC chips in each of the packages 200 and 222 is much simpler than in the ultra thin stack chip package previously discussed and shown in FIGS. 1A and 1C. The simpler wire bonding and the reduction in the number of different vertical levels of wire bonds may improve the yield of good packages over the thin stack chip package, which had three, four or five individual IC chips in each package. The lower number of individual IC chips in each package simplifies both the electrical function testing and the failure analysis of packages 200 and 222, as compared to the thin stack chip package discussed previously and shown in FIG. 1, and thus may have reduced cost of assembled finished packages, as compared to the thin stack chip package which assembles a package using incompletely tested IC chips.

FIG. 2B is a cross sectional side view of an exemplary embodiment. FIG. 2B shows a completed multi chip package 230 comprising a top package 232 and a bottom package 234. Either or both of the individual packages 232 and 234 may have one, two or more IC included within the individual packages. The top package 232 is electrically connected to the bottom package 234 by an interposer 236, thus resulting in shorter electrical signal paths as compared to the folded stack chip package discussed in FIG. 1B, and having no stressed signal conductors at the 180 degree fold of the flex film. The top package may be attached to the interposer 236 by means of solder pads 238 on the top surface of the interposer 236. The interposer 236 may have previously been attached to the lower package 234 by solder pads 240 on the bottom surface of interposer 236, as shown in FIG. 2C. The interposer 236 may be a continuous solid surface covering the entire bottom package 234, or it may be a ring as shown in this illustrative embodiment. The use of a ring interposer may result in thinner overall bottom packages, which in turn may result in an overall reduction in package height. The ring interposer 236 may have the hollow center filled by an encapsulant material 242, which may have a top surface that matches the height of the interposer top surface.

The ring shaped interposer 236, may have a single row of electrical connection pads 238 on the top surface of the interposer 236, as shown in the illustrative embodiment of FIGS. 2B and 2C, or the interposer 236 may have any number of rows of electrical connection pads 238 on the top surface, as shown in FIG. 2D. A bottom package 234 may be fully electrically function tested prior to attachment to the top package 232 to form the package 230, resulting in improved final package yield. The top package 232 may likewise be fully electrically function tested prior to attachment.

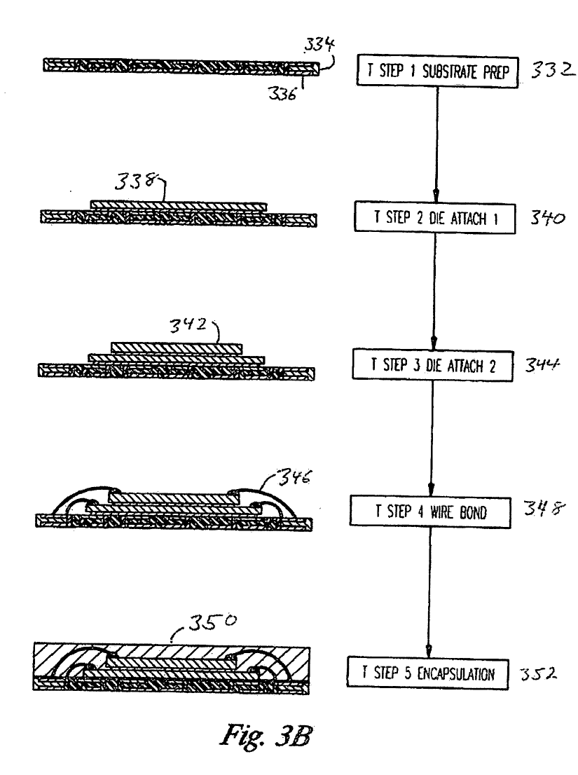

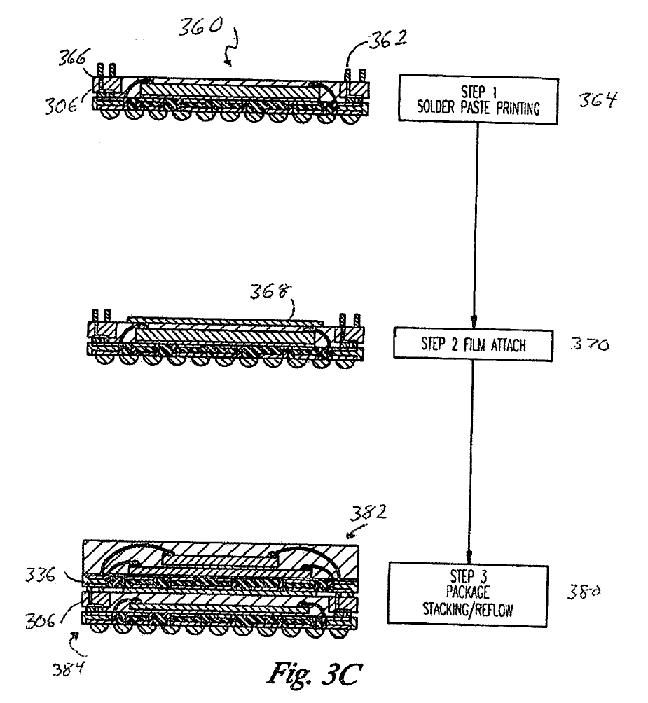

FIG. 3A is a flow chart of an exemplary embodiment of an assembly flow for a bottom portion of a multi-chip package. A bottom package assembly process may begin at step 302 with preparation of a bottom package substrate, which may contain many levels of conductive interconnect on a bottom surface, a top surface or located internally. The bottom package substrate may be screen printed with a patterned layer of solder paste 304, which may be placed on a number of electrical connections on a top surface of the bottom package substrate, for connecting the package substrate to connections on a lower surface of an interposer.

The interposer 306, may be placed on the patterned solder paste at step 308, where the interposer 306 may be aligned such that a number of electrical connections on a bottom surface of the interposer are in contact with the patterned solder paste 304. The combination of bottom package substrate and interposer may then be heated, the patterned solder paste reflowed, to thus solder the interposer to the bottom package substrate. The interposer may have the form of a hollow flat square that is larger than and surrounding the IC chip or chips on the bottom package substrate.

An IC chip 310 may be placed in the approximate center region of the bottom package substrate and physically attached to the package substrate at step 312. The physical attachment of the IC chip may be by epoxy, metal filled epoxy or any other suitable die attach method. If the package is to be a multi-chip package, a second IC chip may be attached by a suitable die attach material to the approximate center region of the first IC 310.

When all of the IC chips are physically attached, they may be electrically attached to some of the electrical connections on the bottom package substrate by means of wire bonds 312 at step 314. If the package is a multi-chip package, selected ones of the electrical I/O pads of the first IC chip may be wire bonded directly to selected ones of the electrical I/O pads of the second IC chip. Alternatively, the first IC may be physically and electrically flip chip mounted to the bottom package substrate, or the second IC may be flip chip mounted to the first IC, or any other suitable method of physical and electrical attachment may be used.

An encapsulant material 316 may now be placed over the IC chip, or chips, on the bottom package substrate to cover and protect the IC chips and the wire bonds connecting the IC to the package substrate at step 318. The encapsulant material 316 may be a polymer, and it may fill the hollow of the interposer to a level approximately even with the top of the interposer, as shown.

Solder balls 320 may be attached to the bottom surface of the bottom package substrate at step 322 to provide a means of attaching the now finished bottom package to a PCB, or other suitable electronic device interconnect means. Alternatively, the bottom of the package substrate may have what is known as a pin grid array, or any other suitable method of attaching the bottom package to an external electronic device. The bottom package is now complete and may be electrically function tested and stored until needed. The electrical function testing may use both the electrical connections on the bottom surface of the bottom package substrate, such as solder balls 320 and the top electrical connections 306 on the top surface of the interposer.

FIG. 3B is a flow chart of an exemplary embodiment of an assembly flow for a top portion of a multi-chip package. A top package assembly process may begin at step 332 with preparation of a top package substrate 334, which may contain many levels of conductive interconnect on a bottom surface, a top surface or located internally. The conductive interconnections on the bottom surface of the top package substrate may include electrical contacts 336 for soldering to a top surface of the interposer.

An IC chip 338 may be placed in the approximate center region of the top package substrate 334 and physically attached to the package substrate at step 340. The physical attachment may be by epoxy. If the package is to be a multi-chip package, a second IC chip 342 may be attached by a suitable die attach material to the approximate center region of the first IC chip 338 at step 344.

When all of the IC chips are physically attached, they may be electrically attached to some of the electrical connections on the top surface of the package substrate 334 by means of wire bonds 346 at step 348. If the top package is to be a multi-chip package, selected ones of the electrical I/O pads of the first IC chip 338 may be wire bonded directly to selected ones of the electrical I/O pads of the second IC chip 342. Alternatively, any other suitable method of physical and electrical attachment may be used, such as flip chip attach.

After the IC chip or chips have been physically and electrically attached to the top package substrate 334, the top surface of the top package substrate and the IC chips may be encapsulated 350 at step 352 to protect the IC chips and interconnections from physical damage and environment contamination. The encapsulation process may use a molding press and a polymer material, or any other suitable protection process.

The top package is now complete and may be electrically function tested and stored until needed for attach to a bottom package. The electrical function testing may use the electrical connections 336 on the bottom surface of the top package substrate.

FIG. 3C is a flow chart of an exemplary embodiment of an assembly flow for attaching a bottom portion of a multi-chip package to a top portion of a multi-chip package. A bottom package 360 may have patterned solder paste 362 applied to a top surface of the bottom package 360 at step 364. The solder paste 362 may be applied to electrical connection pads 366 on the attached interposer 306.

An adhesive film 368 may be attached to the top surface of the bottom package 360 at step 370 to physically attach the bottom package to the top package. The adhesive film may be positioned in the approximate middle of the interposer 306.

The top and bottom packages (which may have been previously individually tested and stored) may be connected at step 380, where the adhesive film 368 may attach the electrical contacts 336 on the bottom of the top package 382 to the electrical contacts and solder paste 362 on the top of the interposer 306. The solder paste 362 on the top surface of the interposer 306 may be heated at step 380 till the solder paste reflows, and cooled until the solder solidifies, thus electrically connecting the top package 382 to the bottom package 384. The completed package may now be electrically function tested and stored until needed. The completed package may use approximately the same PCB area as a single chip package, may have what is known as close electrical coupling between individual IC chips in the top and bottom packages, and may allow the final package assembly to use pre-tested ICs and simple, inexpensive automated assembly techniques.

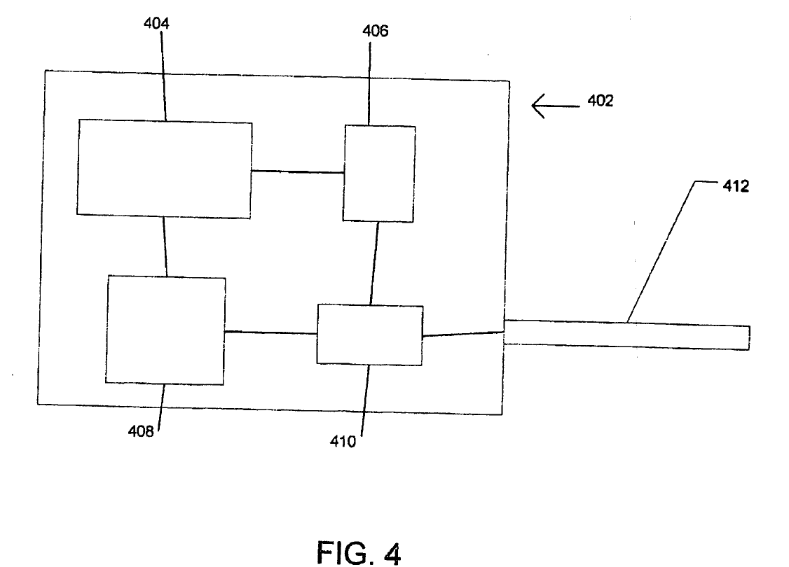

FIG. 4 is a block diagram of an article of manufacture 402 according to various embodiments of the invention. The article of manufacture may comprise one or more of a number of possible elements, such as a communications network, a computer, a memory system, a magnetic or optical disk, some other information storage device, and/or any type of electronic device or system. The article 402 may comprise at least one processor 404 coupled to a machine-accessible medium such as a memory 406, storing associated information (e.g., computer program instructions 408, and/or other data), and an input/output driver 410 coupled to external electrical and electronic devices by various elements, such as bus or cable 412, which when accessed, results in a machine performing such actions as calculating a solution to a mathematical problem. Various ones of the elements of the article 402, for example the memory 406, may have need of PCB space management methods that may use the present invention to place multiple IC chips in about the same amount of PCB area as a single IC package.

Alternatively, the article 402 may comprise a portion or an element of a communications network in two-way communications with other elements of the network by means of the bus or cable 412, or by wireless communications elements included in I/O driver 410, or use both cable and wireless elements. In this illustrative example of an element of a communications network, the two-way communications apparatus may include a coaxial cable, a serial bus, a parallel bus, a twisted pair cable, a dipole antenna, a monopole antenna, a unidirectional antenna, a laser infrared (“IR”) diode emitter/detector, or any other suitable type of communication structure. The processor 404 may accept signals from the I/O driver 410 and perform an operation under the control of a program in memory 406, or use local provisioning information source in computer program instruction area 408. The memory 406, or any one of the elements in this illustrative embodiment, may have PCB space issues that may be improved by use of the disclose arrangement wherein any of the elements may group two or more IC packages into a stacked arrangement that may result in a smaller overall system size. In addition, the processor 404 may benefit from having a part of the memory 406 in the same package, possibly resulting in reduced memory fetch instruction delay.

The accompanying figures that form a part hereof show by way of illustration, and not of limitation, specific embodiments in which the inventive subject matter of the invention may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of the various disclosed embodiments. Combinations of the above embodiments, and other embodiments not specifically described herein, will be apparent to those of skill in the art upon reviewing this description.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope of meaning of the claims. In addition, in the foregoing Detailed Description, it may be seen that various features are grouped together in a single embodiment for the purpose of streamlining this disclosure and increasing its clarity. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

What is claimed is:

1. A method, comprising:
attaching a first integrated circuit to a first surface of an interposer to electrically connect the first integrated circuit to electrical connections in the interposer;
attaching a second integrated circuit to a second surface of the interposer proximate to the first surface to electrically connect the second integrated circuit to the first integrated circuit through the electrical connections in the interposer.

2. The method of claim 1, further comprising a third integrated circuit electrically connected to at least one of the second integrated circuit and the second surface of the interposer.

3. The method of claim 2, further comprising encapsulating the second and the third integrated circuits before electrically connecting to the second surface of the interposer.

4. A method, comprising:
attaching one or more integrated circuits to a top surface of a bottom package substrate, the bottom package substrate including electrical connections for interconnecting the one or more integrated circuits and for connecting the one or more integrated circuits to electrical connections on a bottom surface and top surface of the bottom package substrate;
attaching an interposer to the top surface of the bottom package substrate to electrically connect selected ones of the electrical connections to electrical connections on a top surface of the interposer; and
encapsulating the top surface of the bottom package substrate to form a top surface of a bottom package substantially level with the top surface of the interposer.

5. The method of claim 4, further comprising:
attaching one or more integrated circuits to a top surface of a top package substrate, the top package substrate including electrical connections for interconnecting the one or more integrated circuits and for connecting the one or more integrated circuits to external connections on a bottom surface of the top package substrate; and
encapsulating the one or more integrated circuits and the top surface of the top package substrate to form a top package.

6. The method of claim 5 further comprising attaching external connections on the bottom surface of the top package to electrical connections on the top surface of the interposer to form an electrical connection between the at least one integrated circuit of the top package and the at least one integrated circuit in the bottom package through electrical connections in the interposer.

7. The method of claim 4, further comprising:
the interposer forming a hollow square larger than and surrounding the integrated circuits attached to the top surface of the bottom package substrate; and
attaching the interposer to a peripherally located region of the top surface of the bottom package substrate.

8. The method of claim 4 further comprising electrically testing the one or more integrated circuits attached to the top surface of the bottom package substrate using the electrical connections on the bottom surface of the bottom package substrate and the electrical connections on the top surface of the interposer.

9. The method of claim 5 further comprising electrically testing the one or more integrated circuits of the top package using the external connections on the bottom surface of the top package substrate.

10. The method of claim 6 further comprising electrically testing the top package and the bottom package prior to the forming the electrical connection between the at least one integrated circuit of the top-package and the at least one integrated circuit in the bottom package.

11. A method of packaging integrated circuits, comprising:
assembling a bottom package including at least one integrated circuit electrically, thermally, and physically attached to a top surface of a package body having at least electrical connections on a bottom surface and electrical connections on the top surface;
attaching an interposer having electrical connections on a bottom surface and electrical connections on a top surface to the top surface of the bottom package and electrically contacting the bottom surface electrical connections of the interposer to the top surface electrical connections of the bottom package;
assembling a top package including at least one integrated circuit electrically, thermally and physically attached to a package body having at least electrical connections on a bottom surface; and
electrically contacting the top surface electrical connections of the interposer to the bottom surface electrical connections of the top package.

12. The method of claim 11 further comprising attaching the interposer to the bottom package physically and electrically by soldering substantially all of the electrical connections on the bottom surface of the interposer to substantially all of the electrical connections on the top surface of the bottom package.

13. The method of claim 12 further comprising the interposer forming a hollow square larger than and surrounding the at least one integrated circuit attached to the top surface of the bottom package, and attaching the interposer to a peripherally located region of the top surface of the bottom package.

14. The method of claim 13 further comprising filling the hollow square interposer and the at least one integrated circuit with an encapsulant material to a level approximately level with the top surface of the interposer.

15. The method of claim 14 further comprising the encapsulant-material completely covering at least one the integrated circuit and the at least one integrated circuit attachments to the top surface of the bottom package.

16. The method of claim 11 further comprising attaching the top package to the interposer electrically, thermally and physically by soldering substantially all of the electrical connections on the bottom surface of the top package to substantially all of the electrical connections on the top surface of the interposer.

17. The method of claim 11 further comprising wirebonding the at least one integrated circuit to the bottom package using electrical pads on the at least one integrated circuit.

18. An apparatus, comprising:
a bottom electronic circuit package including at least one integrated circuit and external electrical contacts on a top surface and on a bottom surface;
an interposer having electrical contacts on a top surface and on a bottom surface, disposed in contact with at least some of the external electrical contacts on the top surface of the bottom electronic circuit package;
a top electronic circuit package including at least one integrated circuit and external electrical contacts on a bottom surface; and
the top electronic circuit package having at least some of the external electrical contacts in direct contact with at least some of the electrical contacts on the top surface of the interposer.

19. The apparatus of claim 18 further comprising at least some of the bottom electronic circuit package external electrical contacts comprise solder bumps.

20. The apparatus of claim 18 further comprising the interposer forming a hollow square larger than and surrounding the at least one integrated circuit.

21. The apparatus of claim 20 further comprising the hollow in the interposer is filled to a level approximately equal to a height of the top surface of the interposer and covering the at least one integrated circuit.

22. The apparatus of claim 18 further comprising the top and the bottom electronic circuit package including a plurality of electronic devices including integrated circuits, optical components, discrete transistors, discrete resistors, discrete capacitors and discreet inductors.

23. The apparatus of claim 18 further comprising the direct contact connection between the top electronic circuit package external electrical contacts on a bottom surface and the electrical contacts on the top surface interposer comprises soldering.

24. A communications network, comprising:
a plurality of coupled network elements including a coaxial cable, at least one of the network elements comprising:
a bottom integrated circuit package electrically connected to a bottom surface of an interposer;
a top integrated circuit package electrically connected to a top surface of the interposer; and
the bottom integrated circuit package coupled to the top integrated circuit in electrical communication by conductive signal paths in the interposer.

25. The communications network of claim 24 further comprising the top integrated circuit package including a plurality of integrated circuits and electrical components, and electrically connected to the top surface of the interposer by soldering.

26. The communications network of claim 24 further comprising the bottom package including a plurality of integrated circuits and electrical components, electrically connected by a plurality of top surface electrical connections to the bottom surface of the interposer by soldering.

27. The communications network of claim 26 further comprising the bottom package including a plurality of bottom surface connections disposed to form solder connections to an external circuit.

28. A computer system, comprising:
a plurality of elements including at least calculating elements, memory elements, communication elements, display elements, a coaxial cable and input/output elements, at least one of the elements comprising:
a bottom integrated circuit package electrically connected to a bottom surface of an interposer;
a top integrated circuit package electrically connected to a top surface of the interposer; and
the bottom integrated circuit package coupled to the top integrated circuit in electrical communication by conductive signal paths in the interposer.

29. The computer system of claim 27 further comprising the top integrated circuit package including a plurality of integrated circuits and electrical components, electrically connected to the top surface of the interposer by soldering.

30. The computer system of claim 27 further comprising the bottom package including a plurality of integrated circuits and electrical components, electrically connected by a plurality of top surface electrical connections to the bottom surface of the interposer by soldering.

31. The computer system of claim 30 further comprising the bottom package including a plurality of bottom surface connections disposed to form solder connections to an external circuit.
